(19) United States
(12) Patent Application Publication
(10) Pub. No.: US 2023/0170223 A1
(43) Pub. Date: Jun. 1, 2023

(54) SEMICONDUCTOR DEVICE AND MANUFACTURING METHOD THEREOF

(71) Applicant: WUHAN XINXIN SEMICONDUCTOR MANUFACTURING CO, LTD, Wuhan (CN)

(72) Inventors: Yang WU, Wuhan (CN); Fan YANG, Wuhan (CN); Sheng HU, Wuhan (CN); Liliang GU, Wuhan (CN); Daohong YANG, Wuhan (CN)

(73) Assignee: WUHAN XINXIN SEMICONDUCTOR MANUFACTURING CO, LTD, Wuhan (CN)

(21) Appl. No.: 17/562,034

(22) Filed: Dec. 27, 2021

(30) Foreign Application Priority Data
Nov. 30, 2021 (CN) 202111439561.8

(51) Int. Cl. H01L 21/308; H01L 21/311; H01L 21/768

(52) U.S. Cl. CPC H01L 21/3086; H01L 21/31116; H01L 21/76877

(57) ABSTRACT

A semiconductor device and a manufacturing method thereof are provided. The manufacturing method of a semiconductor device, comprising following steps: providing a substrate and sequentially forming a first mask layer and a second mask layer on the substrate, wherein the second mask layer covers the first mask layer; dry etching the first mask layer using the second mask layer as a mask, wherein the first mask layer has a patterned first opening; and removing the second mask layer and wet etching the substrate using the patterned first mask layer as a mask to form a plurality of trenches on the substrate, wherein the plurality of trenches extend from a surface of the substrate to inside of the substrate, and a cross-sectional width in a cross-section perpendicular to the substrate of the plurality of trenches gradually decreases from the surface of the substrate to the inside of the substrate.

### CROSS REFERENCE TO RELATED APPLICATIONS

This application claims priority of Chinese patent applications No. 202111439561.8 filed Nov. 30, 2021, the contents of which are incorporated herein by reference in their entirety.

### BACKGROUND

### Field

The present disclosure relates to the field of semiconductor manufacturing technology, and more particular, to a semiconductor device and a manufacturing method thereof.

### Background

For silicon-based optoelectronic devices, the surface reflectivity of silicon is very high. If the silicon surface is not treated, its reflectivity to visible light can reach more than 40%, and its reflectivity to near-infrared light is as high as 60% above. Since the reflectivity of silicon crystalline to light is so high so application fields and performances of optoelectronic products made of crystalline silicon are ultimately severely restricted.

It is well known that an absorption efficiency for photons of a material can be improved by increasing a thickness of silicon. However, increases of the thickness of silicon will bring huge challenges to semiconductor processes, which is not cost-effective.

### SUMMARY

Therefore, the present invention provides a method for manufacturing a semiconductor device that can improve the quantum absorption efficiency.

In addition, the present invention also provides a semiconductor device with high competitiveness.

In order to solve the above-mentioned problems, the technical solution provided by the present invention is as follows:

The present invention provides a manufacturing method of a semiconductor device, comprising following steps:
providing a substrate and sequentially forming a first mask layer and a second mask layer on the substrate, wherein the second mask layer covers the first mask layer;
dry etching the first mask layer using the second mask layer as a mask, wherein the first mask layer has a patterned first opening; and
removing the second mask layer and wet etching the substrate using the patterned first mask layer as a mask to form a plurality of trenches on the substrate, wherein the plurality of trenches extend from a surface of the substrate to inside of the substrate, and a cross-sectional width in a cross-section perpendicular to the substrate of the plurality of trenches gradually decreases from the surface of the substrate to the inside of the substrate.

In an optional embodiment of the present invention, each of the plurality of the trenches has a dangling protrusion relative to thereof at the surface of the substrate in the cross-section perpendicular to the substrate.

In an optional embodiment of the present invention, after the step of form the plurality of trenches on the substrate by the wet etching, further comprising:
removing the first mask layer; and
removing the protrusion by a non-mask etching.

In an optional embodiment of the present invention, after the step of removing the protrusion by the non-mask etching, further comprising:

filling an insulating material in the plurality of trenches.

In an optional embodiment of the present invention, after removing the protrusion, the plurality of trenches have a second opening on the surface of the substrate, and a cross-sectional width of the second opening is greater than the cross-sectional width of the first opening in the cross-section perpendicular to the substrate, and a difference between of the cross-sectional widths of the second opening and the first opening is less than 100 nm.

In an optional embodiment of the present invention, the first mask layer is a hard mask layer, and the second mask layer is a photoresist mask layer.

In an optional embodiment of the present invention, a thickness of the second mask layer is less than 2000 Å.

In an optional embodiment of the present invention, the plurality of trenches extends from the surface of the substrate to the inside of the substrate, having an inverted quadrangular pyramid shape.

In an optional embodiment of the present invention, an inclined angle of a side surface of each of the plurality of trenches is 54.7°.

In an optional embodiment of the present invention, a ratio of a depth of the plurality of trenches to a maximum cross-sectional width of the plurality of trenches is equal to 0.5*tan (54.7).

The present invention also provides a semiconductor device manufactured by the above-mentioned manufacturing method of the semiconductor device.

In an optional embodiment of the present invention, each of the plurality of the trenches has a dangling protrusion relative to thereof at the surface of the substrate in the cross-section perpendicular to the substrate.

In an optional embodiment of the present invention, the first mask layer is a hard mask layer, and the second mask layer is a photoresist mask layer.

In an optional embodiment of the present invention, a thickness of the second mask layer is less than 2000 Å.

In an optional embodiment of the present invention, the plurality of trenches extends from the surface of the substrate to the inside of the substrate, having an inverted quadrangular pyramid shape.

In an optional embodiment of the present invention, an inclined angle of a side surface of each of the plurality of trenches is 54.7°.

In an optional embodiment of the present invention, a ratio of a depth of the plurality of trenches to a maximum cross-sectional width of the plurality of trenches is equal to 0.5*tan (54.7).

The present invention proposes a method of manufacturing a semiconductor device by wet-etching a substrate to form a trench by use of the patterned first mask layer (hard mask) as a mask to replace the second mask layer (photoresist) as a mask, which can avoid over-etching of the photoresist in contact with the substrate by the dry etching process, not only forming a trench with a predetermined inclined angle (54.7°) of a side surface to increase the number of reflections of light on the silicon (substrate) surface, enhancing capture ability to incident light energy by the silicon (substrate), and improving the quantum absorption efficiency of the semiconductor device, but also avoiding increase in the trench size caused by over-etching of the photoresist in contact with the substrate, thereby restricting a feature size of the trench and increasing the degree of freedom for designing the trench.

### BRIEF DESCRIPTION OF THE DRAWINGS

In order to more clearly illustrate the embodiments of the present application or the technical solutions in the related art, the drawings to be used in the description of the embodiments or the related art will be briefly introduced below. Obviously, the drawings described below only illustrate some embodiments of the present application, and other drawings can be obtained according to these drawings without any creative effort for those skilled in the art.

FIG. 1 is a flow chart of a manufacturing method of a semiconductor device according to a preferred embodiment of the present invention.

FIG. 2 is a cross-sectional view of a composite structure provided by a preferred embodiment of the present invention.

FIG. 3 is a cross-sectional view of patterning the first mask layer using the second mask layer shown in FIG. 2 as a mask.

FIG. 4 is a cross-sectional view after removing the second mask layer shown in FIG. 3.

FIG. 5 is a cross-sectional view after form a plurality of trenches by etching a substrate with the patterned first mask layer shown in FIG. 4 as a mask.

FIG. 6 is a cross-sectional view after removing the first mask layer in FIG. 5.

FIG. 7 is a cross-sectional view after removing a protrusion over the trench in FIG. 6.

FIG. 8 is a cross-sectional view after form an initial insulating layer by filling an insulating material to a first surface of the substrate and the trenches in FIG. 7.

FIG. 9 is a cross-sectional view after obtaining a semiconductor device by removing the initial insulating layer on the first surface of the substrate shown in FIG. 8.

FIG. 10 is an optical path diagram of the semiconductor device shown in FIG. 9.

### DETAILED DESCRIPTION OF THE ILLUSTRATED EMBODIMENTS

Embodiments of the present disclosure will now be described in conjunction with the accompanying drawings, and it will be apparent that the described embodiments are only a part of the present invention and are not intended to be exhaustive. All other embodiments obtained by one of ordinary skill in the art without creative work are intended to be within the scope of the present disclosure based on the embodiments provided herein. The technical solutions in the embodiments of the present invention will be clearly and completely described below in conjunction with the drawings in the embodiments of the present invention. Obviously, the described embodiments are only a part of the embodiments of the present invention, rather than all the embodiments. Based on the embodiments of the present invention, all other embodiments obtained by those skilled in the art without creative work shall fall within the protection scope of the present invention.

In the description of the present invention, it should be understood that the orientation or positional relationship indicated by the terms “upper”, “lower”, etc. are based on the orientation or positional relationship shown in the drawings, and are only for the convenience of describing the present invention and simplifying the description. It does not indicate or imply that the pointed device or element must have a specific orientation, be configured and operated in a specific orientation, and therefore cannot be understood as a limitation of the present invention. In addition, the terms “first” and “second” are only used for descriptive purposes, and cannot be understood as indicating or implying relative importance or implicitly indicating the number of indicated technical features. Therefore, the features defined with “first” and “second” may explicitly or implicitly include one or more of the features. In the description of the present invention, “plurality” means two or more than two, unless specifically defined otherwise.

The present invention may repeat reference numerals and/or reference letters in different embodiments, and this repetition is for the purpose of simplification and clarity, and does not itself indicate the relationship between the various embodiments and/or settings discussed.

In the prior art, photoresist is often used as a mask in conjunction with a dry etching process to form multiple trenches on the silicon substrate to improve the material’s absorption efficiency of photons. When the photoresist is used as a mask and the dry etching process is used to from the trenches, the photoresist is required to generate by-products to protect the sidewalls of the trenches on silicon to obtain an inclined angle of the side surface. Therefore, the thickness of the photoresist is generally thicker, and the thicker thickness of the photoresist at a place where the photoresist contacts the substrate is severely etched, which will increase the size of the mask at that place, resulting in an increase in the feature size of the trench to be made and out of controllable of the size of the trench. In a first aspect, it is difficult to further restrict the feature size of the trench made by this method, which limits the degree of freedom of the trench design. In a second aspect, the inclined angle of a side surface of the trench made in this way can only be about 70°, which is not the best angle to improve the quantum absorption efficiency.

With respect to the technical problems of the limitation the degree of freedom for the trench design of the existing semiconductor devices and the poor quantum absorption efficiency, the present invention provides a method of manufacturing a semiconductor device by wet-etching a substrate to form a trench by use of the patterned first mask layer (hard mask) as a mask to replace the second mask layer (photoresist) as a mask, which can avoid over-etching of the photoresist in contact with the substrate by the dry etching process, not only forming a trench with a predetermined inclined angle (54.7°) of a side surface to increase the number of reflections of light on the silicon (substrate) surface, enhancing capture ability to incident light energy by the silicon (substrate), and improving the quantum absorption efficiency of the semiconductor device, but also avoiding increase in the trench size caused by over-etching of the photoresist in contact with the substrate, thereby restricting a feature size of the trench and increasing the degree of freedom for designing the trench.

A semiconductor device and a manufacturing method thereof of the present invention will be described in detail below together with specific embodiments.

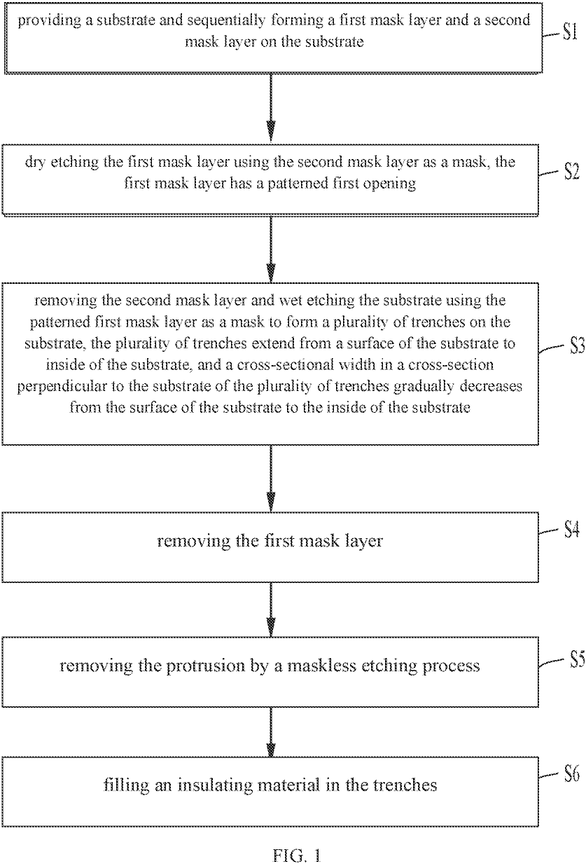

Referring to FIG. 1, a preferred embodiment of the present invention provides a manufacturing method of a semiconductor device 100, comprising:

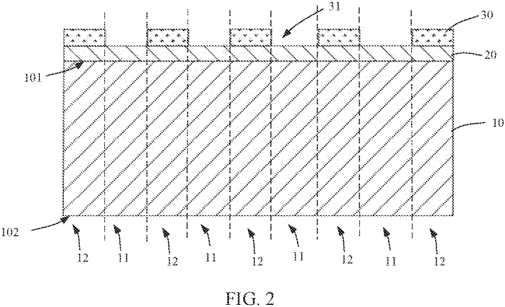

Step S1, referring to FIGS. 1 and 2, a substrate 10 is provided and a first mask layer 20 and a second mask layer 30 are sequentially formed on the substrate 10. The second mask layer 30 covers the first mask layer 20.

In this embodiment, a crystal structure of a material of the substrate 10 is a diamond cubic crystal structure, such as silicon and germanium.

Herein, the substrate 10 comprises a plurality of spacer regions 11 and a plurality of pixel preparation regions 12, and the plurality of spacer regions 11 and the plurality of pixel preparation regions 12 are arranged at intervals. That is, two spacer regions 11 are formed on both sides of a pixel preparation region 12.

The substrate 10 further comprises a first surface 101 and a second surface 102, and the second surface 102 is opposite to the first surface 101.

Step S2, referring to FIGS. 1 to 3, the first mask layer 20 is dry-etched using the second mask layer 30 as a mask, and the first mask layer 20 has a patterned first opening 21.

In this embodiment, the first mask layer 20 is formed on the first surface 101.

In other embodiments, a pad oxide layer (not shown) or a high dielectric constant (HK) dielectric layer (not shown) may also be comprised between the first mask layer 20 and the first surface 101. Herein, the pad oxide layer is used for stress-buffering. The HK dielectric layer is, for example, at least one of aluminum oxide, hafnium oxide, zirconium oxide, or other HK thin films. The HK dielectric layer can increase the light transmittance of the substrate surface and reduce parasitic capacitance.

In this embodiment, a material of the first mask layer 20 is a hard mask. Specifically, a hard mask is an inorganic thin film material generated by chemical vapor deposition (CVD), which comprises main components of TiN, SiN, SiO₂ and the like.

In the present invention, the first mask layer 20 is used as a mask for etching the substrate 10, and a thickness thereof can be determined according to actual needs.

Specifically, since the material of the first mask layer 20 is a hard mask, a thickness of the second mask layer 30 (made of photoresist) is less than an overall thickness of the photoresist in the prior art, and a thickness of the first mask layer 20 is less than a thickness of the photoresist being replaced in the prior art when the first mask layer 20 is used a hard mask is used to replaces a part of the photoresist in the prior art.

Herein, the first mask layer 20 (hard mask) replaces photoresist as a mask, and impact of the plasma on the photoresist during a dry etching process during etching of the substrate or an over-etching to a photoresist solution to the photoresist contacting the substrate during a photolithography process can be reduced, thereby somehow controlling a cross-sectional width of a trench formed in the substrate 10 in a predetermined range.

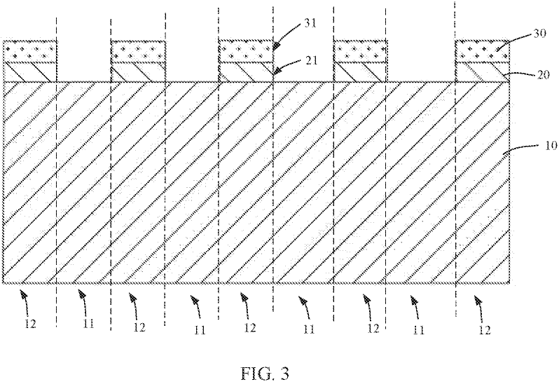

Herein, in FIG. 2 and FIG. 3, the manufacturing method of the patterned first mask layer comprises: firstly, forming a first mask layer 20 on the substrate 10; secondly, forming a second mask layer 30 on the mask layer 20; again, patterning the second mask layer 30, and the second mask layer 30 has a patterned third opening 31. Each third opening 31 respectively opposite to one first opening 21 and one spacing regions 11. After that, the first mask layer 20 is patterned.

Specifically, in this embodiment, the second mask layer 30 may be patterned by a photolithography process.

Specifically, in this embodiment, the patterned second mask layer 30 may be used as a mask, and the first mask layer 20 may be patterned by a dry etching process.

In this embodiment, a material of the second mask layer 30 is photoresist, but it is not limited thereto.

Herein, a thickness of the second mask layer 30 is less than 2000 Å. Preferably, the thickness of the second mask layer 30 ranges from 1000 to 2000 Å. Compared with the thickness of 12000 Å in the prior art, the present invention not only greatly saves amounts of used photoresist but also designs the third opening 31 (mask pattern) with a smaller size and a higher density.

In the present invention, the thickness of the second mask layer 30 is relatively thin, as long as it can satisfy the consumption requirement to the second mask layer 30 that the second mask layer 30 is able to be used as a mask in the subsequent process to pattern the first mask layer through a dry etching process.

Since the first mask layer 20 is a hard mask and the second mask layer 30 is a photoresist. Therefore, the mask layer 20 is not affected by the photolithography solution when the second mask layer 30 is patterned by a photolithography process, and a feature size of the trenches will not be increased due to over-etching at the contact position of the first mask layer 20 and the substrate 10.

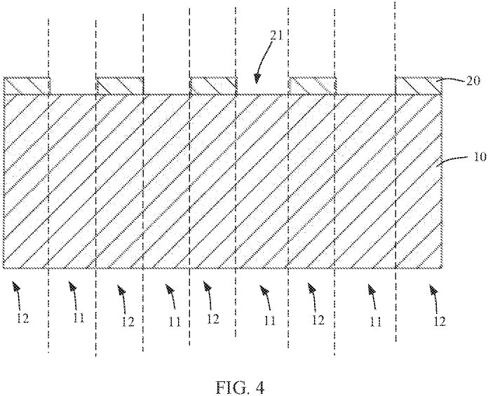

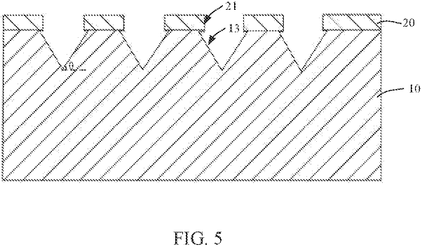

Step S3, referring to FIGS. 1, 4, and 5, the patterned second mask layer 30 is removed, and the substrate 10 is wet etched using the patterned first mask layer 20 as a mask, thereby forming a plurality of trenches 13 on the substrate 10. The plurality of trenches 13 extending from a surface of the substrate 10 to inside of the substrate 10, and a cross-sectional width in a cross-section perpendicular to the substrate 10 of the plurality of trenches 13 gradually decreases from the surface of the substrate 10 to the inside of the substrate 10.

In this embodiment, the plurality of trenches 13 extend from the surface opening of the substrate 10 to the inside of the substrate 10, and have a shape of an inverted triangular pyramid, an inverted quadrangular pyramid, an inverted pentagonal pyramid, an inverted hexagonal pyramid, etc., and preferably have an inverted quadrangular pyramid shape.

In this embodiment, the material of the substrate 10 is silicon, and the trench 13 is formed with a pyramid-like shaped inverted regular quadrangular pyramid composed of four side surfaces of (111) crystal plane and a bottom surface of (100) crystal plane, and an inclined angle θ of a side surface of the trench 13 refers to an inclined angle between a side wall of the trench 13 (i.e., one of the side surfaces of the (111) crystal plane) and a horizontal line passing through an apex of the inverted regular quadrangular pyramid.

Since the wet etching process is well known to those skilled in the art, it will not be further described here.

Specifically, since the wet etching is related to the crystal orientation, and the wet etching is an anisotropic etching. Thus, the wet etching uses silicon atoms of different crystal planes having different etching speeds (i.e., atomic densities and activation energies are not the same, resulting in different etching speeds for silicon atoms on different crystal planes). The side surfaces (i.e., the crystal orientation of the silicon substrate is the (111) plane) have the slowest etching speed, so the etching will eventually end on the side surfaces. A plurality of pyramid-like shaped inverted quadrangular pyramid trenches are thus formed on the silicon surface and are composed of four side surfaces and a bottom surface. The inclined angle of the side surfaces of the trench 13 is 54.7°, and the process angle of 54.7° can significantly improve the quantum efficiency.

Herein, the trenches 13 are directly formed by wet etching, but are not formed by first forming trapezoidal trenches by a first dry etching and then forming an inverted quadrangular pyramid-shaped trench by a second photoresist etching. Not only the process is simplified, but can also avoid damage to sidewalls of the trench by dry etching and avoid the generation of dark currents.

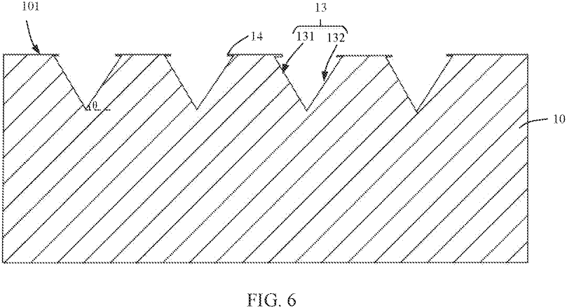

Step S4, referring to FIG. 1 and FIG. 6, the first mask layer 20 is removed.

In step S4, the substrate 10 comprises the plurality of the grooves 13, and each of the plurality of the grooves 13 comprises a first side wall 131 and the second side wall 132. One end of the first side wall 131 is directly connected to the second side wall 132 and the other end is connected to the first surface 101 when the cross-section is a cross-section passing through the apex of the inverted quadrangular pyramid and a midpoint of a side opposite to the apex. Correspondingly, a cross section of the trench 13 is an inverted triangle. In addition, one end of the first side wall 131 is connected to the second side wall 132 through a bottom wall (not shown), and the other end is connected to the first surface 101 when the cross section is a cross section that does not pass through the apex of the inverted quadrangular pyramid and the midpoint of the side opposite to the apex, Correspondingly, a cross section of the trench 13 is in an inverted trapezoid shape. The portions of the first side wall 131 and the second side wall 132 adjacent to the first surface 101 also form a protrusion 14 extending from the first side wall 131 and the second side wall 132 toward each other. That is, on a cross-section perpendicular to the surface of the substrate 10, each of the trenches 13 has a dangling protrusion 14 relative to thereof at the surface of the substrate 10.

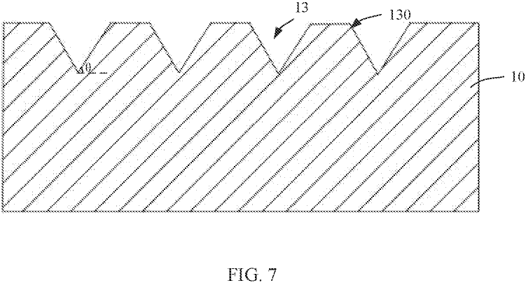

Step S5, referring to FIG. 1 and FIG. 7, the protrusion 14 is removed by a non-mask etching.

Specifically, in step S5, the protrusion 14 and the portion of the substrate 10 on the same horizontal line as the protrusion 14 are also etched away. At this time, the trench 13 comprise a second opening 130. On a cross-section perpendicular to the surface of the substrate 10, a cross-sectional width of the second opening 130 is greater than the cross-sectional width of the first opening 21, and a difference between of the cross-sectional widths of the second opening 130 and the first opening 21 is less than 100 nm. A ratio of a depth of the plurality of trenches 13 to a maximum cross-sectional width of the plurality of trenches 13 is equal to 0.5*tan (54.7), which is approximately equal to 1.753.

Specifically, in the present invention, after forming the inverted quadrangular pyramid-shaped trench (step S4), the first mask layer 20 (hard mask, step S4) is first removed, and the protrusion generated on the inner wall of the trench due to the wet etching is then removed by the non-mask etching (for example, the plasma etching, step S5). Compared with the photoresist etching used to remove the protrusions, the mask layer and other film layers in the prior art, the operations in this embodiment are simpler.

Step S6, referring to FIGS. 1 and 8-9, an insulating layer 40′ is filled in the trench 13 to form the semiconductor device 100.

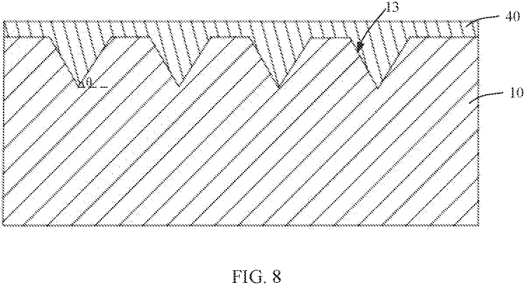

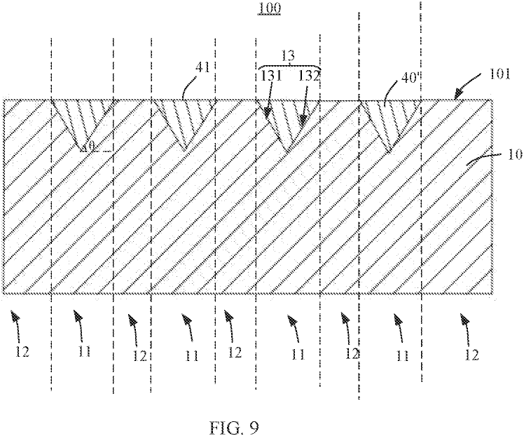

Specifically, step S6 comprises: firstly, referring to FIG. 8, filling the first surface 101 of the substrate 10 and the trench 13 with an insulating material to form an initial insulating layer 40; secondly, referring to FIG. 9, removes the insulating material on the first surface 101 of the substrate 10 through a chemical mechanical polishing (CMP) process, only leaving the insulating material filled in the trench 13 to form the insulating layer 40′.

Herein, please refer to FIG. 9, the present application also provides a semiconductor device 100 formed by the above-mentioned manufacturing method of a semiconductor device. The semiconductor device 100 comprises a substrate 10, the substrate 10 comprises a plurality of spacer regions 11 and a plurality of pixel preparation regions 12, and the plurality of the spacer regions 11 and the plurality of the pixel preparation regions 12 are arranged at intervals. That is, two spacer regions 11 are formed on both sides of a pixel preparation region 12. The substrate 10 further comprises a first surface 101 and a second surface 102, and the second surface 102 is opposite to the first surface 101. The substrate 10 further comprises a plurality of trenches 13, and each trench 13 opposites to one spacing region 11. After that, the first mask layer 20 is patterned. The plurality of trenches 13 concave inward from a surface of the substrate 10 to inside of the substrate 10. The plurality of trenches 13 extend from a surface of the substrate 10 to inside of the substrate 10, and have a shape of an inverted triangular pyramid, an inverted quadrangular pyramid, an inverted pentagonal pyramid, an inverted hexagonal pyramid, etc., and preferably have an inverted quadrangular pyramid shape. The inclined angle of the side surfaces of the trench 13 is 54.7°. A ratio of a depth of the plurality of trenches 13 to a maximum cross-sectional width of the plurality of trenches 13 is equal to 0.5*tan (54.7), which is approximately equal to 1.753. Herein, the semiconductor device 100 further comprises an insulating layer 40′ filling the trench 13 for isolating two adjacent pixel preparation regions 12.

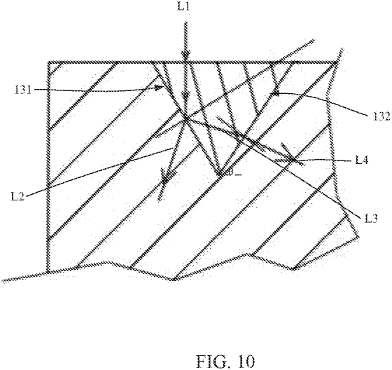

Please refer to FIG. 10, FIG. 10 is an optical path diagram of the semiconductor device 100 provided by the present invention. When the light L1 is incident on the first side wall 131 or the second side wall 132 of the trench 13 from various directions, a part of the light L1, the light L2, is refracted and absorbed by the substrate 10, and another part of the light L1, the light L3, is reflected and incident on the second side wall 132 or the first side wall 131. Parts of the light L3 is refracted on the second side wall 132 or the first side wall 131 and absorbed by the substrate 10, and other parts are reflected by the second side wall 132 or the first side wall 131. This part of the reflected light may be emitted from the opening of the trench 13 to outside, or it is also possible to continue to be refracted and reflected at least once by the first side wall 131 and/or the second side wall 132, thereby increasing the number of reflections and refractions of light on the silicon (substrate 10) surface, enhancing capture ability to incident light energy by the silicon (substrate 10) surface, and improving quantum absorption efficiency of the semiconductor device 100.

The semiconductor device and the manufacturing method thereof provided by the present invention replace at least parts of the second mask layer (photoresist) in the prior art with a first mask layer (hard mask), and then the first mask layer is patterned by use of the second mask layer (photoresist) as a mask layer to transfer the pattern of the second mask layer (photoresist) to the first mask layer and remove the thinned second mask layer (photoresist), and then the substrate is wet-etched to form a trench by use of the patterned first mask layer as a mask. Therefore, firstly, a part of the second mask layer (photoresist) is replaced with a first mask layer of a different material from the second mask layer (photoresist), thus an overall thickness of the second mask layer (photoresist) can be reduced, so that a pattern (third opening) with a smaller size and a higher density can be obtained on the second mask layer (photoresist). After that, the second mask layer (photoresist) is used as a mask layer, and the pattern of the second mask layer (photoresist) can be transferred to the first mask layer to obtain a first opening. Then, the patterned first mask layer is used as a mask and the trench is formed on the substrate by wet etching, which can avoid over-etching of the photoresist in contact with the substrate by the dry etching process, thereby avoiding increase in the trench size caused by over-etching of the photoresist in contact with the substrate. Secondly, since the material of the first mask layer is a hard mask, the total thickness of the first mask layer and the second mask layer required to make trenches of the same size is less than the total thickness of the photoresist required in the prior art. Therefore, when the first mask layer is patterned using the second mask layer as a mask, an amount of by-product produced on the photoresist is less during the dry etching process. Therefore, the size of the first opening obtained by patterning the first mask layer and the size of the third opening obtained by patterning the second mask layer have little change, so that a smaller size and a higher density can be obtained. Therefore, the size and density of the third opening in the pattern of the second mask layer can be adjusted according to actual needs to limit the size of the trench (the actual second opening) and increase the degree of freedom for designing the trench. Thirdly, forming trenches by using the first mask layer (hard mask) as a mask and using a wet etching process to etch the substrate not only can control the size and density of the trenches in a predetermined range, but also forming a trench with a predetermined inclined angle (54.7°) of a side surface to increase the number of reflections of light on the silicon (substrate) surface, enhancing capture ability to incident light energy by the silicon (substrate, thereby improving the quantum absorption efficiency of the semiconductor device.

In addition, the trenches are directly formed by wet etching, but are not formed by first forming trapezoidal trenches by a first dry etching and then forming an inverted quadrangular pyramid-shaped trench by a second photoresist etching. Not only the process is simplified, but can also avoid damage to sidewalls of the trench by dry etching and avoid the generation of dark currents.

In addition, before the wet etching, the second mask layer (photoresist) is first removed, which can prevent side-products affecting the substrate etching and the trench size formed by reaction of solutions used in the wet etching and the photoresist.

Furthermore, after the trench is formed, the first mask layer (hard mask) is removed first, and then the protrusion generated on the inner wall of the trench by wet etching are removed by a non-mask etching (blank etching). Compared with the photoresist etching used to remove the protrusions, the mask layer and other film layers in the prior art, the operations in this embodiment are simpler.

In summary, although the present invention has been disclosed as above in preferred embodiments, the above-mentioned preferred embodiments are not intended to limit the present invention. Those of ordinary skill in the art can make various modifications without departing from the spirit and scope of the present invention. Such changes and modifications, so the protection scope of the present invention is subject to the scope defined by the claims.

What is claimed is:

1. A manufacturing method of a semiconductor device, comprising following steps:
providing a substrate and sequentially forming a first mask layer and a second mask layer on the substrate, wherein the second mask layer covers the first mask layer;
dry etching the first mask layer using the second mask layer as a mask, wherein the first mask layer has a patterned first opening; and
removing the second mask layer and wet etching the substrate using the patterned first mask layer as a mask to form a plurality of trenches on the substrate, wherein the plurality of trenches extend from a surface of the substrate to inside of the substrate, and a cross-sectional width in a cross-section perpendicular to the substrate of the plurality of trenches gradually decreases from the surface of the substrate to the inside of the substrate.

2. The manufacturing method of a semiconductor device according to claim 1, wherein each of the plurality of the trenches has a dangling protrusion relative to thereof at the surface of the substrate in the cross-section perpendicular to the substrate.

3. The manufacturing method of a semiconductor device according to claim 2, after the step of form the plurality of trenches on the substrate by the wet etching, further comprising:
removing the first mask layer; and
removing the protrusion by a non-mask etching.

4. The manufacturing method of a semiconductor device according to claim 3, after the step of removing the protrusion by the non-mask etching, further comprising:
filling an insulating material in the plurality of trenches.

5. The manufacturing method of a semiconductor device according to claim 3, wherein after removing the protrusion, the plurality of trenches have a second opening on the surface of the substrate, and a cross-sectional width of the second opening is greater than the cross-sectional width of the first opening in the cross-section perpendicular to the substrate, and a difference between of the cross-sectional widths of the second opening and the first opening is less than 100 nm.

6. The manufacturing method of a semiconductor device according to claim 1, wherein the first mask layer is a hard mask layer, and the second mask layer is a photoresist mask layer.

7. The manufacturing method of a semiconductor device according to claim 6, wherein a thickness of the second mask layer is less than 2000 Å.

8. The manufacturing method of a semiconductor device according to claim 1, wherein the plurality of trenches extends from the surface of the substrate to the inside of the substrate, having an inverted quadrangular pyramid shape.

9. The manufacturing method of a semiconductor device according to claim 8, wherein an inclined angle of a side surface of each of the plurality of trenches is 54.7°.

10. The manufacturing method of a semiconductor device according to claim 9, wherein a ratio of a depth of the plurality of trenches to a maximum cross-sectional width of the plurality of trenches is equal to 0.5*tan (54.7).

11. A semiconductor device manufactured by following steps:
providing a substrate and sequentially forming a first mask layer and a second mask layer on the substrate, wherein the second mask layer covers the first mask layer;
dry etching the first mask layer using the second mask layer as a mask, wherein the first mask layer has a patterned first opening; and
removing the second mask layer and wet etching the substrate using the patterned first mask layer as a mask to form a plurality of trenches on the substrate, wherein the plurality of trenches extend from a surface of the substrate to inside of the substrate, and a cross-sectional width in a cross-section perpendicular to the substrate of the plurality of trenches gradually decreases from the surface of the substrate to the inside of the substrate.

12. The semiconductor device according to claim 11, wherein each of the plurality of the trenches has a dangling protrusion relative to thereof at the surface of the substrate in the cross-section perpendicular to the substrate.

13. The semiconductor device according to claim 11, wherein the first mask layer is a hard mask layer, and the second mask layer is a photoresist mask layer.

14. The semiconductor device according to claim 11, wherein a thickness of the second mask layer is less than 2000 Å.

15. The semiconductor device according to claim 11, wherein the plurality of trenches extends from the surface of the substrate to the inside of the substrate, having an inverted quadrangular pyramid shape.

16. The semiconductor device according to claim 11, wherein an inclined angle of a side surface of each of the plurality of trenches is 54.7°.

17. The semiconductor device according to′ claim 11, wherein a ratio of a depth of the plurality of trenches to a maximum cross-sectional width of the plurality of trenches is equal to 0.5*tan (54.7).
